(19) United States
(12) Patent Application Publication
(10) Pub. No.: US 2023/0387075 A1
(43) Pub. Date: Nov. 30, 2023

(54) SEMICONDUCTOR PACKAGE

(71) Applicant: MEDIATEK INC., Hsinchu City (TW)

(72) Inventors: Yi-Lin TSAI, Hsinchu City (TW); Wen-Sung HSU, Hsinchu City (TW); Nai-Wei LIU, Hsinchu City (TW)

(21) Appl. No.: 18/303,693

(22) Filed: Apr. 20, 2023

Related U.S. Application Data
(60) Provisional application No. 63/345,056, filed on May 24, 2022.

(51) Int. Cl. H01L 25/065; H01L 23/538; H01L 23/31; H01L 23/00

(52) U.S. Cl. CPC H01L 25/0655; H01L 23/5385; H01L 23/5383; H01L 23/3185; H01L 24/16; H01L 24/32; H01L 24/73; H01L 2224/16227; H01L 2224/32225; H01L 2224/73204

(57) ABSTRACT

A semiconductor package includes an interposer over a substrate that includes interconnect traces, a redistribution structure on the interposer, a first semiconductor structure, a second semiconductor structure and a third semiconductor structure on the redistribution structure. The first semiconductor structure includes a first semiconductor die and a first encapsulant that encapsulates the first semiconductor die. The second semiconductor structure includes a second semiconductor die and a second encapsulant that encapsulates the second semiconductor die. The third semiconductor structure is disposed adjacent to a corner or an edge of the substrate in a top plan view of the substrate. The third semiconductor structure includes a third semiconductor die and a third encapsulant that encapsulates the third semiconductor die. The third semiconductor structure is electrically insulated from the substrate, the first semiconductor structure and the second semiconductor structure.

### CROSS REFERENCE TO RELATED APPLICATIONS

This application is based on, and claims priority of U.S. Provisional Application No. 63/345,056 filed on May 24, 2022, the entirety of which is incorporated by reference herein.

### BACKGROUND OF THE INVENTION

### Field of the Invention

The present invention relates to a semiconductor package, and, in particular, to a semiconductor package with reduced stress and improved coplanarity.

### Description of the Related Art

A smaller semiconductor package structure that takes up less space than the previous generation of semiconductor package structures is required. One technological solution is heterogeneous integration, which is to integrate multiple semiconductor dies within the same package. As such, the cost of manufacturing the semiconductor package can be reduced while the semiconductor package is still able to provide high levels of performance and high density. In some semiconductor packages, an interposer or a bridge structure may be utilized to provide interconnections between the semiconductor dies.

Although existing semiconductor packages have been adequate for their intended purposes, they have not been entirely satisfactory in all respects. For example, one or more dummy silicon dies may be placed over the interposer of a semiconductor package in the arrangement of the semiconductor package. However, it causes the semiconductor package to have a stress imbalance and poor coplanarity (COP). Therefore, there are still some problems to be overcome in regards to semiconductor packages in the field of semiconductor integrated circuit technology.

### BRIEF SUMMARY OF THE INVENTION

An embodiment of the present disclosure provides a semiconductor package. An exemplary embodiment of a semiconductor package includes an interposer over a substrate that includes interconnect traces, a redistribution structure on the interposer, a first semiconductor structure on the redistribution structure and a second semiconductor structure on the redistribution structure. The first semiconductor structure includes a first semiconductor die and a first encapsulant that encapsulates the first semiconductor die. The second semiconductor structure includes a second semiconductor die and a second encapsulant that encapsulates the second semiconductor die. In some embodiments, the semiconductor package further includes a third semiconductor structure on the redistribution structure. The third semiconductor structure is disposed adjacent to a corner or an edge of the substrate in a top plan view of the substrate. The third semiconductor structure includes a third semiconductor die and a third encapsulant that encapsulates the third semiconductor die. In some embodiments, the third semiconductor structure is electrically insulated from the substrate, the first semiconductor structure and the second semiconductor structure.

An embodiment of the present disclosure provides a semiconductor package. An exemplary embodiment of a semiconductor package includes a first structure and a second structure over a substrate that includes interconnect traces, and the second structure is adjacent to the first structure. In some embodiments, each of the first structure and the second structure includes an interposer over a substrate, a redistribution structure on the interposer, a first semiconductor structure, a second semiconductor structure and a third semiconductor structure on the redistribution structure. The first semiconductor structure includes a first semiconductor die and a first encapsulant that encapsulates the first semiconductor die. The second semiconductor structure includes a second semiconductor die and a second encapsulant that encapsulates the second semiconductor die. The third semiconductor structure includes a third semiconductor die and a third encapsulant that encapsulates the third semiconductor die. In some embodiments, the third semiconductor structure is electrically insulated from the substrate, the first semiconductor structure and the second semiconductor structure. In some embodiments, the third semiconductor structures of the first structure and the second structure are disposed adjacent to two corners or two edges of the substrate in a top plan view of the substrate.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIG. 1 is a top view of an intermediate stage of a semiconductor package, in accordance with some embodiments of the present disclosure;

FIG. 2 is a cross-sectional view of an intermediate stage of a semiconductor package, in accordance with some embodiments of the present disclosure;

FIG. 3A is a top view of an intermediate stage of a semiconductor package, in accordance with some embodiments of the present disclosure;

FIG. 3B is a top view of an intermediate stage of a semiconductor package, in accordance with some embodiments of the present disclosure;

FIG. 3C is a cross-sectional view taken along line 3C-3C of the semiconductor package of FIG. 3B, in accordance with some embodiments of the present disclosure;

FIG. 4 is a top view of an intermediate stage of a semiconductor package, in accordance with some embodiments of the present disclosure; and

FIG. 5 is a top view of an intermediate stage of a semiconductor package, in accordance with some embodiments of the present disclosure.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is determined by reference to the appended claims.

The inventive concept is described fully hereinafter with reference to the accompanying drawings, in which exemplary embodiments of the inventive concept are shown. The advantages and features of the inventive concept and methods of achieving them will be apparent from the following exemplary embodiments that will be described in more detail with reference to the accompanying drawings. It should be noted, however, that the inventive concept is not limited to the following exemplary embodiments, and may be implemented in various forms. Accordingly, the exemplary embodiments are provided only to disclose the inventive concept and let those skilled in the art know the category of the inventive concept. Also, the drawings as illustrated are only schematic and are non-limiting. In the drawings, the size of some of the elements may be exaggerated for illustrative purposes and not drawn to scale. The dimensions and the relative dimensions do not correspond to actual dimensions in the practice of the invention.

The terminology used herein is for the purpose of describing particular embodiments only and is not intended to limit the invention. As used herein, the singular terms “a,” “an” and “the” are intended to include the plural forms as well, unless the context clearly indicates otherwise. As used herein, the term “and/or” includes any and all combinations of one or more of the associated listed items. It should be understood that when an element is referred to as being “connected” to or “contacting” another element, it may be directly connected to or contacting the other element, or intervening elements may be present.

Similarly, it should be understood that when an element such as a layer, region or substrate is referred to as being “on” another element, it can be directly on the other element or intervening elements may be present. In contrast, the term “directly” means that there are no intervening elements. It should be understood that the terms “comprises”, “comprising”, “includes” and/or “including”, when used herein, specify the presence of stated features, integers, steps, operations, elements, and/or components, but do not preclude the presence or addition of one or more other features, integers, steps, operations, elements, components, and/or groups thereof.

Furthermore, spatially relative terms, such as “under”, “over”, “lower”, “upper” and the like, may be used herein for ease of description to describe one element or feature's relationship to another element(s) or feature(s) as illustrated in figures. The spatially relative terms are intended to encompass different orientations of the device in use or operation in addition to the orientation depicted in the figures. It should be understood that although the terms first, second, third etc. may be used herein to describe various elements, these elements should not be limited by these terms. These terms are only used to distinguish one element from another element. Thus, a first element in some embodiments could be termed a second element in other embodiments without departing from the teachings of the present invention. Exemplary embodiments of aspects of the present inventive concept explained and illustrated herein include their complementary counterparts. The same or similar reference numerals or reference designators denote the same or similar elements throughout the specification.

Some embodiments of the disclosure are described. It should be noted that additional procedures can be provided before, during, and/or after the stages described in these embodiments. Some of the stages that are described can be replaced or eliminated for different embodiments. Additional features can be added to the semiconductor package. Some of the features described below can be replaced or eliminated for different embodiments. Although some embodiments are discussed with procedures performed in a particular order, these procedures may be performed in another logical order.

According to some embodiments of the present disclosure, semiconductor packages are described below. In some embodiments, the semiconductor structures that are arranged adjacent to the opposite corners and/or edges of the interposer and the substrate have similar structural configurations (e.g., packages) to reduce and balance the overall stress of the semiconductor package. For example, one semiconductor structure that is disposed adjacent to a corner or an edge of the substrate is configured as a dummy package (i.e. does not provide any real electrical function). Thus, the coplanarity (COP) of the entire semiconductor package can be improved. In addition, the thermal reliability of the semiconductor packages in accordance with some embodiments of the present disclosure is significantly improved.

Semiconductor packages in accordance with some embodiments of the present disclosure are provided below. It should be noted that the present disclosure is not limited to the exemplified package structures provided herein. Those structures described below are merely for providing some applicable examples of the configurations of the semiconductor packages.

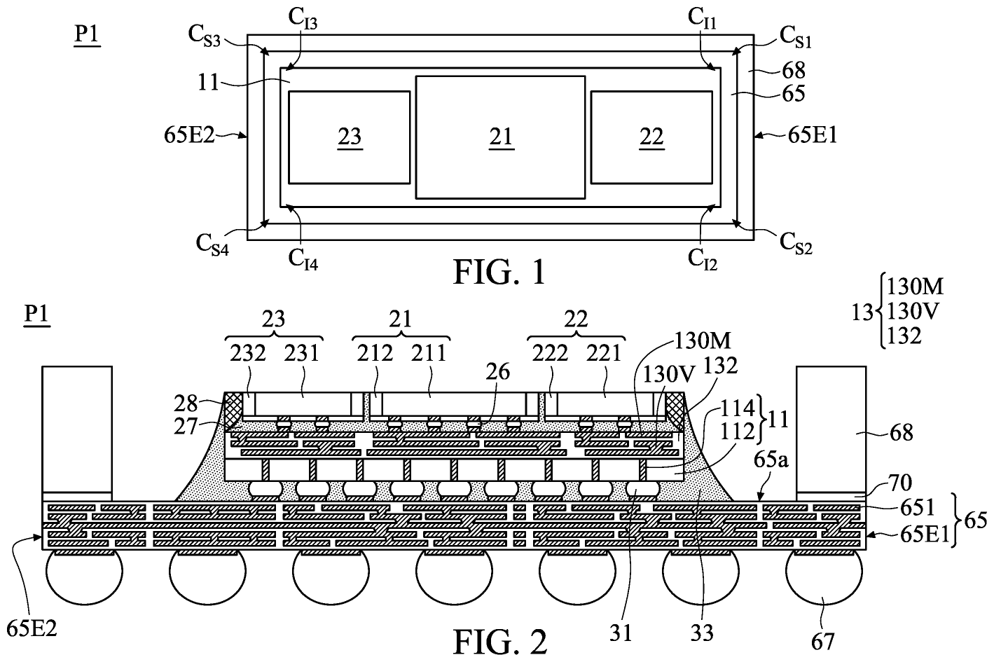

FIG. 1 is a top view of an intermediate stage of a semiconductor package, in accordance with some embodiments of the present disclosure. FIG. 2 is a cross-sectional view of an intermediate stage of a semiconductor package, in accordance with some embodiments of the present disclosure. To simplify the diagram, a semiconductor package P1 that includes only three semiconductor structures above an interposer 11 is depicted in FIG. 1 and FIG. 2. Some of those semiconductor structures are coupled to a substrate 65 through the interposer 11. The details are described below.

Referring to FIG. 1, a semiconductor package P1 is provided. In some embodiments, a first semiconductor structure 21, a second semiconductor structure 22 and a third semiconductor structure 23 that are disposed in one region are depicted. The region corresponds to an interposer 11 that includes several conductive pillars (e.g. through-silicon-vias; abbreviated as “TSVs”; FIG. 2). In some embodiments, the semiconductor structures that have similar structural configurations (e.g., packages) and are arranged adjacent to the opposite corners (and/or edges) of the interposer 11 and the opposite corners (and/or edges) of the substrate 65 would reduce and balance the overall stress, thereby improving coplanarity (COP) of the semiconductor package P1. For example, when a semiconductor structure that is disposed on the interposer 11 and arranged adjacent to a corner (or an edge) of the interposer 11 and a corner (or an edge) of the substrate 65 is an active device or a passive device in the form of a package, another semiconductor structure that is disposed on the interposer 11 and arranged adjacent to the opposite corner (or the opposite edge) of the interposer 11 and the opposite corner (or the opposite edge) of the substrate 65 may be a dummy package (instead of a dummy silicon die), so as to reduce and balance the overall stress of the entire semiconductor package P1.

As shown in FIG. 1, in some embodiments, the first semiconductor structure 21 is disposed in the middle of the interposer 11 (and in the middle of the substrate 65) in a top plan view. The second semiconductor structure 22 and the third semiconductor structure 23 are arranged at opposite sides of the first semiconductor structure 21 and adjacent to two opposite corners and opposite edges of the interposer 11. Also, the second semiconductor structure 22 and the third semiconductor structure 23 are arranged at the opposite corners and opposite edges of the substrate 65. For example, the second semiconductor structure 22 is disposed adjacent to the corner C_{I1} (or the corner C_{I2}) of the interposer 11 and the corner C_{S1} (or the corner C_{S2}) of the substrate 65, while the third semiconductor structure 23 is disposed adjacent to the corner C_{I3} (or the corner C_{I4}) of the interposer 11 and the corner C_{S3} (or the corner C_{S4}) of the substrate 65. In addition, the second semiconductor structure 22 is disposed adjacent to the first edge 65E1 of the substrate 65, and the third semiconductor structure 23 is disposed adjacent to the second edge 65E2 of the substrate 65. The second edge 65E2 is opposite the first edge 65E1. When the first semiconductor structure 21 and the second semiconductor structure 22 are active devices or passive device provided in the form of packages, the third semiconductor structure 23 may be a package with real electrical function, or a dummy package (instead of a dummy silicon die) without any electrical function if necessary.

In some embodiments, the third semiconductor structure 23 is a dummy structure that is not electrically coupled to other semiconductor structures, and this dummy structure is configured in the form of a package (abbreviated as “dummy package”). In some embodiments, the third semiconductor structure 23 is electrically insulated from the first semiconductor structure 21, the second semiconductor structure 22, the interposer 11 and the substrate 65. In other words, That is, no electrical signal is transmitted (or no signal path is provided) between the third semiconductor structure 23 and any of the substrate 65, the interposer 11, the first semiconductor structure 21 and the second semiconductor structure 22.

Referring to FIG. 2, a semiconductor package P1 includes an interposer 11, a redistribution structure 13 on the interposer 11, and three semiconductor structures (including the first semiconductor structure 21, the second semiconductor structure 22 and the third semiconductor structure 23) on the redistribution structure 13, and a substrate 65 underlying and electrically connected to the interposer 11, in accordance with some embodiments of the present disclosure. Specifically, as shown in FIG. 2, the interposer 11 includes a semiconductor base 112 and several conductive pillars (such as through-vias) 114 that penetrate through the semiconductor base 112. In some embodiments, the semiconductor base 112 is a silicon substrate, or a substrate including another suitable material.

In some embodiments, a redistribution structure 13 is formed on the interposer 11, such as on the top surface of the interposer 11. It should be noted that the top surface of the interposer 11 is defined as the surface facing away from the substrate 65. The redistribution structure 13 may include several dielectric layers 132 and conductive traces in the dielectric layers 132. The conductive traces may include metal lines 130M and conductive vias 130V connecting to the metal lines 130M. The metal lines 130M and conductive vias 130V of the redistribution structure 13 are electrically connected to the underlying interposer 11.

In some embodiments, the metal lines 130M have fine widths and fine pitches. In addition, the conductive material of the metal lines 130M and the conductive vias 130V may include a metal, like copper, titanium, tungsten, aluminum, or another suitable material. The dielectric layers 132 may be formed of a photo-sensitive material such as polybenzoxazole (PBO), polyimide, benzocyclobutene (BCB) or another suitable material. The dielectric layers 132 may be formed by spin coating, lamination, chemical vapor deposition (CVD), another suitable method, or a combination thereof.

As shown in FIG. 2, in some embodiments, the first semiconductor structure 21, the second semiconductor structure 22 and the third semiconductor structure 23 are disposed on the redistribution structure 13. In this exemplary embodiment, the first semiconductor structure 21 and the second semiconductor structure 22 have real electrical functions and are provided in the form of packages, while the third semiconductor structure 23 has no real electrical function (i.e. no electrical signal is transmitted from the third semiconductor structure 23 to the first semiconductor structure 21 and the second semiconductor structure 22) but is in the form of a package.

Specifically, in some embodiments, the first semiconductor structure 21 includes a first semiconductor die 211 and a first encapsulant 212. The first semiconductor die 211 is surrounded and encapsulated by the first encapsulant 212. The first encapsulant 212 may cover the sidewalls of the first semiconductor die 211. The first encapsulant 212 prevents the first semiconductor die 211 from damages due to, for example, the stress, the chemicals and/or the moisture. In some embodiments, the second semiconductor structure 22 includes a second semiconductor die 221 and a second encapsulant 222. The second semiconductor die 221 is surrounded and encapsulated by the second encapsulant 222. The first encapsulant 212 may cover the sidewalls of the second semiconductor die 221. The second encapsulant 222 prevents the second semiconductor die 221 from damages due to, for example, the stress, the chemicals and/or the moisture. In some embodiments, the third semiconductor structure 23 includes a third semiconductor die 231 and a third encapsulant 232. The third semiconductor die 231 is surrounded and encapsulated by the third encapsulant 232. The third encapsulant 232 may cover the sidewalls of the third semiconductor die 231. The third encapsulant 232 prevents the third semiconductor die 231 from the stress, the chemicals and/or the moisture.

In some embodiments, the first semiconductor structure 21 and the second semiconductor structure 22 are active devices. For example, the first semiconductor structure 21 and the second semiconductor structure 22 may each independently include a system-on-chip (SoC) die, a logic device, a memory device, a radio frequency (RF) device, the like, or any combination thereof. For example, the first semiconductor structure 21 and the second semiconductor structure 22 may each independently include a microcontroller (MCU), a microprocessor (MPU), a power management integrated circuit (PMIC), a global positioning system (GPS) device, a central processing unit (CPU), a graphics processing unit (GPU), a dynamic random access memory (DRAM) controller, a static random-access memory (SRAM), a high bandwidth memory (HBM), the like, or any combination thereof. In some other embodiments, the first semiconductor structure 21 and/or the second semiconductor structure 22 include passive devices, such as resistors, capacitors, inductors, the like, or a combination thereof. The first semiconductor structure 21 and the second semiconductor structure 22 may include the same or different devices. For example, the first semiconductor structure 21 includes a SoC device, and the second semiconductor structure 22 includes a HBM. In some embodiments, the first semiconductor structure 21 and the second semiconductor structure 22 may be manufactured following the same process node, for example, following 7 nm node. In some other embodiments, the first semiconductor structure 21 and the second semiconductor structure 22 may be manufactured following different process nodes, for example, the first semiconductor structure 21 may be manufactured following 7 nm node, and the second semiconductor structure 22 may be manufactured following 6 nm node, but not limited.

In this exemplary embodiment, although no electrical signal is provided by the third semiconductor structure 23, the third semiconductor structure 23 that is disposed adjacent to the corner C_{I3} (or the corner C_{I4}) of the interposer 11 and the corner C_{S3} (or the corner C_{S4}) of the substrate 65 has similar or identical structural configuration as the second semiconductor structure 22. Therefore, the overall stress of the entire semiconductor package P1 can be reduced and balanced, so that the coplanarity (COP) of the semiconductor package P1 can be improved. In some embodiments, the arrangement of the second semiconductor die 221 and the second encapsulant 222 of the second semiconductor structure 22 is similar or identical to the arrangement of the third semiconductor die 231 and the third encapsulant 232 of the third semiconductor structure 23. For example, the structural configuration of the second semiconductor die 221 and the second encapsulant 222 is similar or identical to the structural configuration of the third semiconductor die 231 and the third encapsulant 232. In one example, the second semiconductor die 221 and the third semiconductor die 231 each may have a configuration of a high bandwidth memory (HBM), or another type of memory/device. In one example, the third encapsulant 232 and the second encapsulant 222 may include the same one or more materials. Accordingly, the difference of the thermal expansion between the third semiconductor structure 23 (that is disposed adjacent to the corner C_{I3} or the corner C_{I4} of the interposer 11 and adjacent to the corner C_{S3} or the corner C_{S4} of the substrate 65) and the second semiconductor structure 22 (that is disposed adjacent to the opposite corner C_{I1} or the corner C_{I2} of the interposer 11 and the opposite corner C_{S1} or the corner C_{S2} of the substrate 65) can be reduced. Also, the overall stresses of the entire semiconductor package P1 can be reduced and balanced. Thus, the coplanarity (COP) of the semiconductor package P1 can be improved, in accordance with some embodiments of the present disclosure.

The first encapsulant 212, the second encapsulant 222 and the third encapsulant 232 each may be a molding compound, which may include a base material and filler particles in the base material. In some embodiments, the base material includes a polymer, a resin, an epoxy, or the like. The base material may be a carbon-based polymer. The filler particles may be the particles of a dielectric material(s) such as SiO₂, Al₂O₃, silica, the compound of iron (Fe), the compound of sodium (Na), or the like, and may have spherical shapes. The first encapsulant 212, the second encapsulant 222 and the third encapsulant 232 may be applied by compression molding, transfer molding, or another suitable molding method.

According to this exemplary embodiment, the first semiconductor structure 21 and the second semiconductor structure 22 have real electrical functions, while no electrical signal is provided by the third semiconductor structure 23. There are many ways to make the third semiconductor structure 23 provide no electrical signal. For example, a die that has no real electrical function (e.g. fails to meet the requirements of electrical properties of a functional die) can be selected as the third semiconductor die 231 and then encapsulated by the third encapsulant 232 to form the third semiconductor structure 23. In some examples, the third semiconductor die 231 of the third semiconductor structure 23 is grounded. In some examples, interconnections between the third semiconductor die 231 and other electrical components of the third semiconductor structure 23 have not been completed yet. In some examples, there is no electrical path constructed between the third semiconductor die 231 of the third semiconductor structure 23 and any of the interposer 11, the first semiconductor structure 21, the second semiconductor structure 22 and the substrate 65. Accordingly, no electrical signal is transmitted between the third semiconductor structure 23 and any of the other semiconductor structures that provide normal electrical functions (such as the first semiconductor structure 21 and the second semiconductor structure 22) and the substrate 65, in accordance with some embodiments of the present disclosure.

For example, the first semiconductor structure 21 includes a SoC device, the second semiconductor structure 22 includes a high bandwidth memory (HBM) device, and the third semiconductor structure 23 includes a dummy HBM device. That is, the third semiconductor structure 23 has a HBM structure (including a HBM and an encapsulant surrounding the HBM) as the second semiconductor structure 22, but does not provide any real HBM function.

In addition, the semiconductor package P1 further includes conductive components 26 disposed between the redistribution structure 13 and the lower surfaces of the first semiconductor structure 21, the second semiconductor structure 22 and the third semiconductor structure 23, in accordance with some embodiments of the present disclosure. As shown in FIG. 2, the first semiconductor structure 21, the second semiconductor structure 22 and the third semiconductor structure 23 are bonded to the redistribution structure 13 through the conductive components 26. In some embodiments, the conductive components 26 that are positioned under the semiconductor structures include conductive materials, such as metal. The conductive components 26 may include microbumps, controlled collapse chip connection (C4) bumps, ball grid array (BGA) balls, the like, or a combination thereof. It should be noted that the first semiconductor structure 21 and the second semiconductor structure 22 are electrically connected to the interposer 11 by the redistribution structure 13 and the conductive components 26, while the third semiconductor structure 23 is electrically insulated from the interposer 11, in accordance with some embodiments of the present disclosure.

After the first semiconductor structure 21, the second semiconductor structure 22 and the third semiconductor structure 23 are bonded to the redistribution structure 13 through the conductive components 26, an underfill material is provided to fill the spaces between the semiconductor structures (i.e. the first semiconductor structure 21, the second semiconductor structure 22 and the third semiconductor structure 23) and the interposer 11 to provide structural support. Also, the underfill material compensates for different coefficients of thermal expansion (CTE) between the semiconductor structures and the interposer 11.

As shown in FIG. 2, in some embodiments, the semiconductor package P1 includes a first underfill layer 27 that surrounds the conductive components 26 and fills the gaps between the conductive components 26. According to a conventional semiconductor package, it includes one or more dummy silicon dies (e.g. “naked die”; without any encapsulant or molding compound to encapsulate the die) on the interposer, and the underfill material may be in direct contact with the dummy silicon die. Compared to the conventional semiconductor package, the semiconductor package P1 includes the third semiconductor structure 23 (i.e. a “dummy package” that does not provide electrical signal and is configured in the form of a package) and the first underfill layer 27, wherein the first underfill layer 27 is adjacent to or in direct contact with the third encapsulant 232 of the third semiconductor structure 23 (FIG. 2), in accordance with some embodiments of the present disclosure.

In some embodiments, the first underfill layer 27 is a polymer material layer. For example, the first underfill layer 27 may include epoxy or the like. The polymer material may be dispensed with capillary force after the conductive components 26 are formed between the redistribution structure 13 and the semiconductor structures (such as the first semiconductor structure 21, the second semiconductor structure 22 and the third semiconductor structure 23). Then, the polymer material may be cured using a suitable curing process, such as a thermal cure process, a ultra-violet (UV) cure process, or the like, so as to form the first underfill layer 27. In some other embodiments, the first underfill layer 27 includes non-conductive paste (NCP), non-conductive film (NCF), the like, or a combination thereof.

In addition, in some embodiments, an encapsulating material (such as a molding compound) is formed on the interposer 11 and covers the first semiconductor structure 21, the second semiconductor structure 22, the third semiconductor structure 23 and the first underfill layer 27. Then, a portion of the encapsulating material is removed, such as by a grinding process or another suitable process, to exposed the top surfaces of the first semiconductor structure 21, the second semiconductor structure 22 and the third semiconductor structure 23. The remaining portion of the encapsulating material can be referred to as an encapsulant 28, as shown in FIG. 2. In some embodiments, the top surface of the encapsulant 28 may be level with the top surfaces of the first semiconductor structure 21, the second semiconductor structure 22 and the third semiconductor structure 23. It should be noted that the top surfaces of the first semiconductor structure 21, the second semiconductor structure 22 and the third semiconductor structure 23 are defined as the surfaces facing away from the interposer 11 and the substrate 65.

In addition, the semiconductor package P1 further includes a plurality of conductive components 31 disposed between the interposer 11 and a substrate 65, in accordance with some embodiments of the present disclosure. The conductive components 31 are formed on the bottom surface of the interposer 11. In some embodiments, the conductive components 31 are electrically connected to the conductive pillars (such as through-vias) 114 of the interposer 11.

The conductive components 31 may be solder balls, metal pillars, controlled collapse chip connection (C4) bumps, micro bumps, electroless nickel-electroless palladium-immersion gold technique (ENEPIG) formed bumps, or the like. The conductive components 31 may include a conductive material such as copper, aluminum, gold, nickel, silver, palladium, tin, solder, another suitable material, or a combination thereof. In some embodiments, the conductive components 31 are formed by initially forming a layer of solder through evaporation, electroplating, printing, solder transfer, ball placement, or another suitable method. Once a layer of solder has been formed on the structure, a reflow may be performed in order to shape the material into the desired bump shapes. In another embodiment, the conductive components 31 include metal pillars (such as a copper pillar) formed by a sputtering, printing, electro plating, electroless plating, chemical vapor deposition (CVD), or another suitable method. The metal pillars may be solder free and have substantially vertical sidewalls. In some embodiments, a metal cap layer (not shown) is formed on the top of the metal pillars. The metal cap layer may include nickel, tin, tin-lead, gold, silver, palladium, indium, nickel-palladium-gold, nickel-gold, another suitable material or a combination thereof and may be formed by a plating process. In this embodiment, the conductive components 31 are controlled collapse chip connection (C4) bumps.

After the conductive components 31 are formed on the bottom surface of the interposer 11, the interposer 11 over which the semiconductor structures (e.g., the first semiconductor structure 21, the second semiconductor structure 22 and the third semiconductor structure 23) are formed is mounted to the substrate 65 by the conductive components 31. The conductive components 31 that are disposed between the interposer 11 and the substrate 65 provide electrical connections between the interconnect traces 651 of the substrate 65, the conductive pillars (such as through-vias) 114 of the interposer 11 and the redistribution structure 13 on the interposer 11.

It should be noted that the first semiconductor structure 21 and the second semiconductor structure 22 are electrically connected to the substrate 65 by the conductive components 26, the redistribution structure 13, the interposer 11 and the conductive components 31, while the third semiconductor structure 23 is electrically insulated from the substrate 65, in accordance with some embodiments of the present disclosure. Although the third semiconductor structure 23 in the form of a package does not transmit any electrical signal to any of the first semiconductor structure 21 and the second semiconductor structure 22 and the substrate 65, it does reduce and balance the overall stress of the substrate 65, thereby improving the coplanarity (COP) of the semiconductor package P1.

In addition, in some embodiments, the semiconductor package P1 further includes a second underfill layer 33 that fills the spaces between the interposer 11 and the substrate 65 to provide structural support. The second underfill layer 33 compensates for different coefficients of thermal expansion (CTE) between the interposer 11 and the substrate 65, in accordance with some embodiments of the present disclosure. Also, the second underfill layer 33 surrounds the conductive components 31 and fills the gaps between the conductive components 31. Also, the second underfill layer 33 covers the sidewalls of the interposer 11 and adjoins the encapsulant 28. Thus, in this exemplary embodiment, the second underfill layer 33 and the encapsulant 28 encapsulate all of the electrical components (such as the first semiconductor structure 21, the second semiconductor structure 22, the third semiconductor structure 23, the conductive components 26, the redistribution structure 13, the interposer 11 and the conductive components 31) of the semiconductor package P1, as shown in FIG. 2.

Materials and methods for forming the second underfill layer 33 can be the same as or similar to those of the first underfill layer 27, which are not repeated herein. In some embodiments, the second underfill layer 33 and the first underfill layer 27 include the same material. In some other embodiments, the second underfill layer 33 and the first underfill layer 27 include different materials.

In addition, in some embodiments, the semiconductor package P1 further includes a frame 68 attached to the top surface 65a of the substrate 65 by an adhesive layer 70. The frame 68 and the adhesive layer 70 surround the first semiconductor structure 21, the second semiconductor structure 22, the third semiconductor structure 23, the conductive components 26, the redistribution structure 13, the first underfill layer 27, the encapsulant 28, the interposer 11, the conductive components 31 and the second underfill layer 33. In some embodiments, the frame 68 and the adhesive layer 70 are separated from the second underfill layer 33 by a gap. In addition, the substrate 65 has a first edge 65E1 and a second edge 65E2 opposite to the first edge 65E1. In some embodiments, the first edge 65E1 and the second edge 65E2 of the substrate 65 are coplanar with the sidewalls of the frame 68 and the adhesive layer 70.

The frame 68 may be, for example, made of materials such as copper or aluminum alloy, another metal material with higher mechanical strength. The frame 68 can be used to prevent warpage of the substrate 65, so as to protect and maintain the substrate 65 in a relatively stable shape when the temperature changes, and to increase the mechanical strength of the entire structure of the semiconductor package P1. Thus, the frame 68 maintains the stability of the semiconductor package P1. In addition, the arrangement of the frame 68 can enhance the mechanical strength of the semiconductor package, reduce the possibility of warping or cracking of the semiconductor package P1, and improve the reliability of the semiconductor package P1.

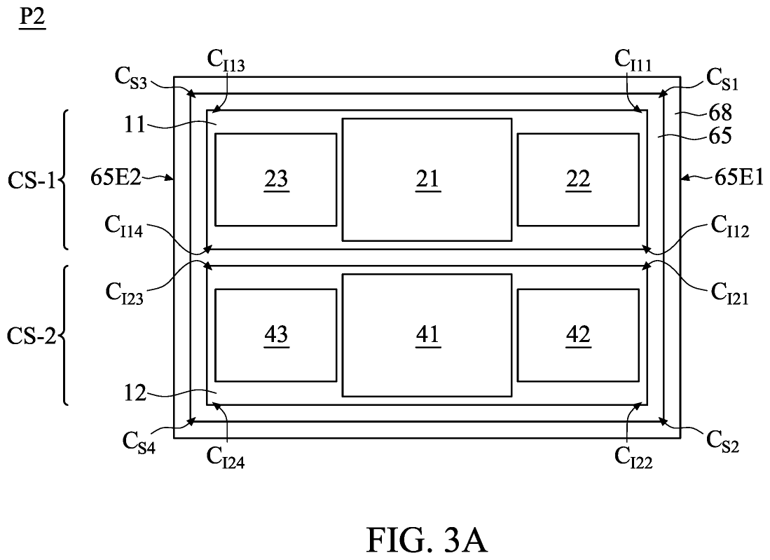

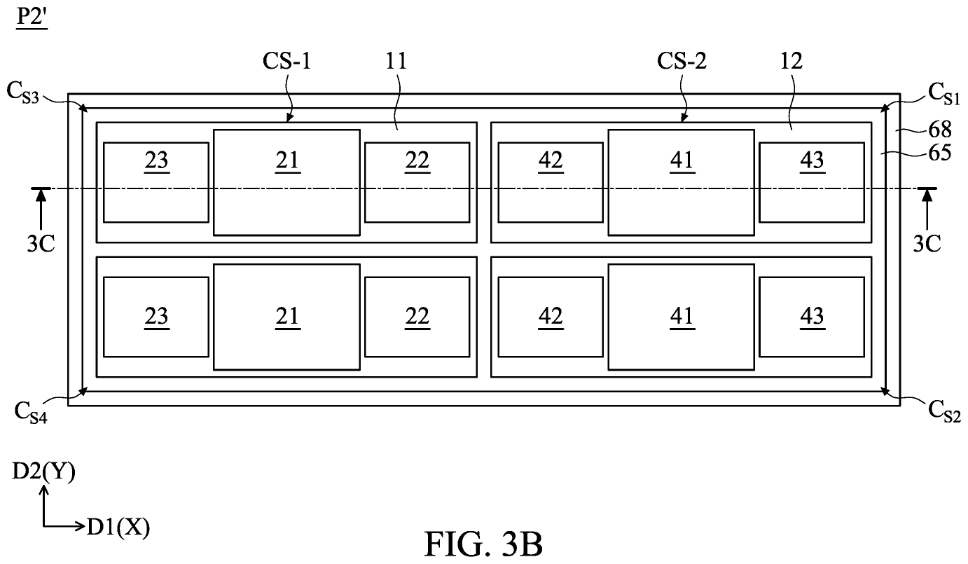

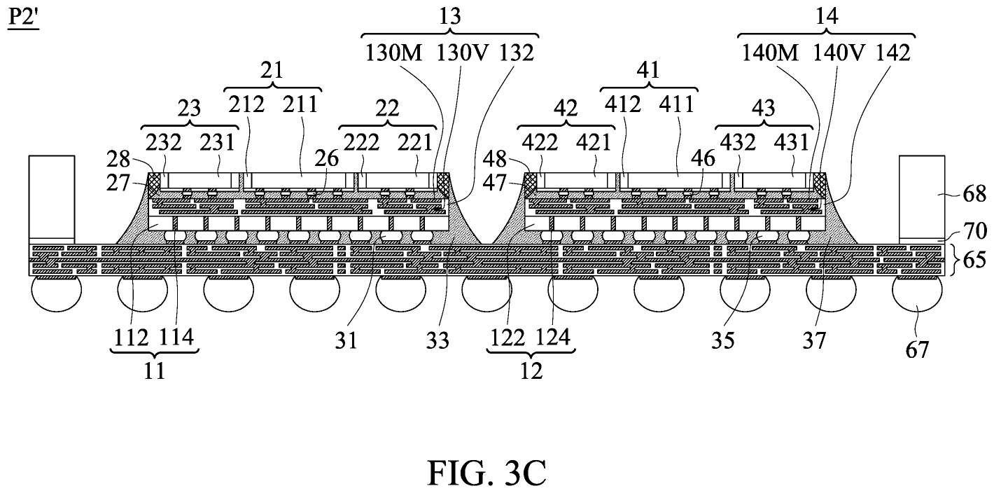

Although one interposer 11 bonded to the substrate 65 of the semiconductor package P1 is depicted in FIG. 1 and FIG. 2, the present disclosure is not limited thereto. A semiconductor package may include two or more interposers over the substrate 65. FIG. 3A is a top view of an intermediate stage of a semiconductor package, in accordance with some embodiments of the present disclosure. The same or similar reference numerals or reference designators denote the same or similar elements (such as components or layers) in FIG. 1 and FIG. 3A. For the purpose of brevity, the materials of the same or similar components/layers and processes of forming those components/layers are not repeated herein.

Referring to FIG. 3A, a semiconductor package P2 with two structures over a substrate 65 is provided. In FIG. 3A, each structure may include an interposer and the features on the interposer, which are similar to or the same as the interposer 11 and the features on the interposer 11 in FIG. 1. The semiconductor package P2 may include a first structure CS-1 and a second structure CS-2 over the substrate 65.

Specifically, in some embodiments, the first structure CS-1 includes an interposer 11 over the substrate 65, a redistribution structure (not shown in FIG. 3A, but has the same or similar structure of the redistribution structure 13 in FIG. 2) on the interposer 11, and the semiconductor structures (including a first semiconductor structure 21, a second semiconductor structure 22 and a third semiconductor structure 23) on the redistribution structure.

In this exemplary embodiment, the first semiconductor structure 21 and the second semiconductor structure 22 have real electrical functions. For example, the first semiconductor structure 21 and the second semiconductor structure 22 each include an active device and/or a passive device. In some embodiments, the second semiconductor structure 22 and the third semiconductor structure 23 are disposed at opposite sides of the first semiconductor structure 21. Specifically, as shown in FIG. 3A, the second semiconductor structure 22 is disposed adjacent to the corner C_{I11} (or the corner C_{I12}) of the interposer 11 and the corner C_{S1} of the substrate 65. The third semiconductor structure 23 is disposed adjacent to the corner C_{I13} (or the corner C_{I14}) of the interposer 11 and the corner C_{S3} of the substrate 65. The third semiconductor structure 23 is electrically insulated from the substrate the first semiconductor structure 21 and the second semiconductor structure 22. That is, no electrical signal is transmitted from the third semiconductor structure 23 to any other electrical components. Thus, in this exemplary embodiment, the third semiconductor structure 23 can be referred to as a dummy structure. In one example, the first semiconductor structure 21 includes a SoC device, the second semiconductor structure 22 includes a HBM, and the third semiconductor structure 23 is a dummy structure that is configured as a HBM package. It should be noted that the present disclosure is not limited to the device/memory types exemplified herein.

In some embodiments, the first semiconductor structure 21 includes a first semiconductor die 211 and a first encapsulant 212 that surrounds and encapsulates the first semiconductor die 211. The second semiconductor structure 22 includes a second semiconductor die 221 and a second encapsulant 222 that surrounds and encapsulates the second semiconductor die 221. The third semiconductor structure 23 includes a third semiconductor die 231 and a third encapsulant 232 that surrounds and encapsulates the third semiconductor die 231. In some embodiments, the third semiconductor structure 23 has similar or identical structural configuration as the second semiconductor structure 22 to reduce and balance the stress of the semiconductor package P2. In FIG. 3A, the stress of the interposer 11 and the stress of the upper portion of the substrate 65 in a top plan view of the substrate 65 can be reduced and balanced. Thus, the coplanarity (COP) of the semiconductor package P2 can be improved.

For the purpose of brevity, the materials and methods for forming the components (such as the interposer 11, the first semiconductor structure 21, the second semiconductor structure 22 and the third semiconductor structure 23) of the semiconductor package P2 in FIG. 3A can be the same as the materials and methods for forming the related components of the semiconductor package P1 in FIG. 2, which are not repeated herein. In addition, other electrical components for forming the semiconductor package P2, such as the redistribution structure, the conductive components for connecting the interposer 11 and the redistribution structure, and the conductive components for connecting the interposer 11 and the substrate 65, the underfill material layers and the substrate 65 can be referred to the aforementioned descriptions, which are not repeated herein.

Similarly, in some embodiments, the second structure CS-2 includes another interposer 12 over the substrate 65, another redistribution structure (not shown in FIG. 3A, but has the same or similar structure of the redistribution structure 13 in FIG. 2) on the interposer 12, and the semiconductor structures (including a fourth semiconductor structure 41, a fifth semiconductor structure 42 and a sixth semiconductor structure 43) over the interposer 12. The interposer 12 is spaced apart from the interposer 11.

For the purpose of brevity, the materials and methods for forming the components (such as the interposer 12, the fourth semiconductor structure 41, the fifth semiconductor structure 42 and the sixth semiconductor structure 43) of the semiconductor package P2 in FIG. 3A can be the same as the related components of the semiconductor package P1 in FIG. 2, which are not repeated herein. In addition, other electrical components of the semiconductor package P2, such as the redistribution structure, the conductive components for connecting the interposer 12 and the redistribution structure, and the conductive components for connecting the interposer 12 and the substrate 65, the underfill material layers and the substrate 65, have been described in the aforementioned embodiment and are not repeated herein.

In some embodiment, the first structure CS-1 and the second structure CS-2 have identical combination of the semiconductor structures. For example, the first semiconductor structure 21 over the interposer 11 and the fourth semiconductor structure 41 over the interposer 12 may have similar or identical electrical function and/or structural configuration. The second semiconductor structure 22 over the interposer 11 and the fifth semiconductor structure 42 over the interposer 12 may have similar or identical electrical function and/or structural configuration. The third semiconductor structure 23 over the interposer 11 and the sixth semiconductor structure 43 over the interposer 12 may have similar or identical electrical function and/or structural configuration.

In some embodiments, the fourth semiconductor structure 41 and the fifth semiconductor structure 42 have real electrical functions, while the sixth semiconductor structure 43 does not transmit electrical signal to other semiconductor structures that are over the interposers 11 and 12 and the substrate 65. In some embodiments, the fifth semiconductor structure 42 and the sixth semiconductor structure 43 are disposed at opposite sides of the fourth semiconductor structure 41. Specifically, as shown in FIG. 3A, the fifth semiconductor structure 42 is disposed adjacent to the corner C_{I21} (or the corner C_{I22}) of the interposer 12 and the corner C_{S2} of the substrate 65, while the sixth semiconductor structure 43 is disposed adjacent to the corner C_{I23} (or the corner C_{I24}) of the interposer 12 and the corner C_{S4} of the substrate 65. The sixth semiconductor structure 43 is electrically insulated from the substrate 65, the fourth semiconductor structure 41 and the fifth semiconductor structure 42. In addition, in some embodiments, the sixth semiconductor structure 43 over the interposer 12 is electrically insulated from the first semiconductor structure 21, the second semiconductor structure 22 and the third semiconductor structure 23 over the interposer 11. That is, no electrical signal is transmitted from the sixth semiconductor structure 43 to any other components on the interposers 11 and 12. In one example, the fourth semiconductor structure 41 includes a SoC device, the fifth semiconductor structure 42 includes a HBM, and the sixth semiconductor structure 43 is a dummy structure that is configured as a HBM package. It should be noted that the present disclosure is not limited to the device/memory types provided herein.

In some embodiments, the fourth semiconductor structure 41, the fifth semiconductor structure 42 and the sixth semiconductor structure 43 each include a semiconductor die (not shown in FIG. 3A) and an encapsulant (not shown in FIG. 3A) that surrounds and encapsulates the semiconductor die. The semiconductor dies and the encapsulants of the fourth semiconductor structure 41, the fifth semiconductor structure 42 and the sixth semiconductor structure 43 can be the same as, or similar to, the semiconductor dies (e.g., 211, 221, 231) and the encapsulants (e.g., 212, 222, 232) of the first semiconductor structure 21, the second semiconductor structure 22 and the third semiconductor structure 23 of the semiconductor package P1 (FIG. 2) that are described in the embodiments above, and therefore the descriptions of the materials and configurations of those semiconductor structures are not repeated herein. In some embodiments, the sixth semiconductor structure 43 has similar or identical structural configuration as the fifth semiconductor structure 42 to reduce and balance the stress of the semiconductor package P2. In FIG. 3A, the stress of the interposer 12 and the stress of the lower portion of the substrate 65 in a top plan view of the substrate 65 can be reduced and balanced. Thus, the coplanarity (COP) of the semiconductor package P2 can be improved.

FIG. 3B is a top view of an intermediate stage of a semiconductor package, in accordance with some embodiments of the present disclosure. FIG. 3C is a cross-sectional view taken along line 3C-3C of the semiconductor package of FIG. 3B, in accordance with some embodiments of the present disclosure. The same or similar reference numerals or reference designators denote the same or similar elements (such as components or layers) in FIG. 3A and FIG. 3B. In addition, the same or similar reference numerals or reference designators denote the same or similar elements (such as components or layers) in FIG. 3C and FIG. 2. For the purpose of brevity, the materials of the same or similar components/layers and processes of forming those components/layers are not repeated herein.

The difference between the semiconductor package P2 in FIG. 3A and the semiconductor package P2′ in FIG. 3B and FIG. 3C is the number and arrangement of the interposers over the substrate 65. In this exemplary embodiment, the semiconductor package P2′ includes two or more first structures CS-1 and two or more second structures CS-2 over the substrate 65. As shown in FIG. 3B, the first structures CS-1 and the second structures CS-2 are arranged side by side in the first direction D1 (e.g. X− direction) in a top plan view of the substrate 65.

Referring to FIG. 3B and FIG. 3C, in some embodiments, each of the first structures CS-1 includes an interposer 11 over the substrate 65, a redistribution structure 13 on the interposer 11, and the semiconductor structures (including the first semiconductor structure 21, the second semiconductor structure 22 and the third semiconductor structure 23) on the redistribution structure 13. For the purpose of brevity, structural details and materials of those components of the first structure CS-1 have been described in the aforementioned embodiment and are not repeated herein.

In some embodiments, each of the second structures CS-2 includes an interposer 12 over the substrate 65, a redistribution structure 14 (FIG. 3C) on the interposer 12, and the semiconductor structures (including the fourth semiconductor structure 41, the fifth semiconductor structure 42 and the sixth semiconductor structure 43) over the interposer 12. The interposer 12 is spaced apart from the interposer 11.

Specifically, in this exemplary embodiment, the fourth semiconductor structure 41 includes a fourth semiconductor die 411 and a fourth encapsulant 412 that encapsulates the fourth semiconductor die 411. The fifth semiconductor structure 42 includes a fifth semiconductor die 421 and a fifth encapsulant 422 that encapsulates the fifth semiconductor die 421. The sixth semiconductor structure 43 includes a sixth semiconductor die 431 and a sixth encapsulant 432 that encapsulates the sixth semiconductor die 431. The fourth semiconductor structure 41, the fifth semiconductor structure 42 and the sixth semiconductor structure 43 of the semiconductor package P2′ in FIG. 3C can be the same as, or similar to, the first semiconductor structure 21, the second semiconductor structure 22 and the semiconductor structure 23 of the semiconductor package P1 in FIG. 2, respectively. Structural details and materials of the semiconductor dies and the encapsulants of the fourth semiconductor structure 41, the fifth semiconductor structure 42 and the sixth semiconductor structure 43 are not repeated herein.

In this exemplary embodiment, the interposer 12 includes a semiconductor base 122 and several conductive pillars (such as through-vias) 124 that penetrate through the semiconductor base 122. In some embodiments, the semiconductor base 122 is a silicon substrate, or a substrate including another suitable material. The redistribution structure 14 may include several dielectric layers 142 and conductive traces in the dielectric layers 142. The conductive traces may include metal lines 140M and conductive vias 140V connecting to the metal lines 140M. The metal lines 140M and conductive vias 140V of the redistribution structure 14 are electrically connected to the interposer 12.

In addition, in some embodiments, the semiconductor package P2′ further includes several conductive components 46 disposed between the redistribution structure 14 and the semiconductor structures (e.g. the fourth semiconductor structure 41, the fifth semiconductor structure 42 and the sixth semiconductor structure 43), and several conductive components 35 disposed between the interposers 12 and the substrate 65. Materials and methods for forming the conductive components 46 and 35 of the semiconductor package P2′ in FIG. 3C can be the same as the conductive components 26 and 31 of the semiconductor package P1 in FIG. 2, which are not repeated herein.

In some embodiments, the semiconductor package P2′ further includes a first underfill layer 47 that surrounds the conductive components 46 and fills the gaps between the conductive components 46, and a second underfill layer 37 that fills the spaces between the interposer 12 and the substrate 65 to provide structural support. Materials and methods for forming the first underfill layer 47 and the second underfill layer 37 of the semiconductor package P2′ in FIG. 3C can be the same as the first underfill layer 27 and the second underfill layer 33 of the semiconductor package P1 in FIG. 2, which are not repeated herein. In addition, an encapsulant 48 is further formed on the interposer 12 and covers the semiconductor structures (e.g. the fourth semiconductor structure 41, the fifth semiconductor structure 42 and the sixth semiconductor structure 43) and the first underfill layer 47. Materials and methods for forming the encapsulant 48 of the semiconductor package P2′ in FIG. 3C can be the same as the encapsulant 28 of the semiconductor package P1 in FIG. 2, which are not repeated herein.

In this exemplary embodiment, the third semiconductor structure 23 is disposed adjacent to the corner C_{S3} of the substrate 65, and the sixth semiconductor structure 43 is disposed adjacent to the corner C_{S1} of the substrate 65. At least one of the third semiconductor structure 23 and the sixth semiconductor structure 43 is a dummy package (instead of a dummy silicon die), so as to reduce and balance the overall stress and improve coplanarity (COP) of the substrate 65 of the semiconductor package P2′.

In one example, the first semiconductor structure 21 and the fourth semiconductor structure 41 each include a SoC device. The second semiconductor structure 22 and the fifth semiconductor structure 42 each include a HBM device. The third semiconductor structure 23 and the sixth semiconductor structure 43 that are disposed adjacent to opposite corners of the substrate 65 are dummy HBM packages. The dummy HBM packages are configured in the forms of HBM packages but cannot provide any real HBM function. Accordingly, the stress of the interposers 11 and 12 and the substrate 65 of the semiconductor package P2′ can be reduced and balanced, thereby improving the coplanarity (COP) of the semiconductor package P2′.

Although three semiconductor structures connected to one interposer is depicted in FIG. 1, FIG. 2 and FIGS. 3A-3C, the present disclosure is not limited thereto. A semiconductor package may include more semiconductor structures that are integrated on one interposer. Dummy package structures may be arranged adjacent to suitable corners or edges of the interposer (and/or adjacent to suitable corners or edges of the substrate) to reduce and balance the overall stress, so the coplanarity (COP) of a semiconductor package can be improved.

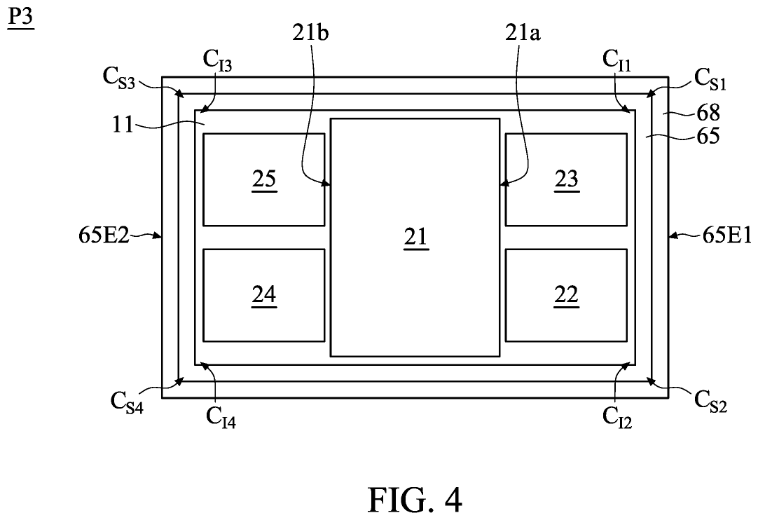

FIG. 4 is a top view of an intermediate stage of a semiconductor package, in accordance with some embodiments of the present disclosure. The same or similar reference numerals or reference designators denote the same or similar elements (such as components or layers) in FIG. 1 and FIG. 4. For the purpose of brevity, the materials of the same or similar components/layers and processes of forming those components/layers are not repeated herein.

Referring to FIG. 4, a semiconductor package P3 includes an interposer 11 over the substrate 65, a redistribution structure (not shown in FIG. 4, but has the same or similar structure of the redistribution structure 13 in FIG. 2) on the interposer 11, and several semiconductor structures on the redistribution structure. In this exemplary embodiment, five semiconductor structures, such as a first semiconductor structure 21, a second semiconductor structure 22, a third semiconductor structure 23, a fourth semiconductor structure 24 and a fifth semiconductor structure 25, are disposed on the interposer 11, as shown in FIG. 4.

For the purpose of brevity, structural details and materials of the semiconductor structures, the redistribution structure, the interposer 11, the substrate 65 and other related components (such as the conductive components and the underfill layers) of the semiconductor package P3 in FIG. 4 can be the same as, or similar to, the related components of the semiconductor package P1 in FIG. 1 and FIG. 2, which are not repeated herein.

In addition, the semiconductor dies and the encapsulants of the first semiconductor structure 21, the second semiconductor structure 22 and the third semiconductor structure 23 can be the same as, or similar to the semiconductor structures of the semiconductor package P1 (FIG. 1 and FIG. 2), and the details are not repeated herein. The fourth semiconductor structure 24 may include a fourth semiconductor die and a fourth encapsulant that encapsulates the fourth semiconductor die (not shown in FIG. 4). The fifth semiconductor structure 25 may include a fifth semiconductor die and a fifth encapsulant that encapsulates the fifth semiconductor die (not shown in FIG. 4). The fourth semiconductor die and the fifth semiconductor die can be the same as, or similar to, the second semiconductor die 221 and the third semiconductor die 231 that are described in the embodiments above. The fourth encapsulant and the fifth encapsulant can be the same as, or similar to the second encapsulants 222 and the third encapsulants 232 that are described in the embodiments above. Therefore, the descriptions of the materials and configurations of the related components of those semiconductor structures are not repeated herein.

In some embodiments, the first semiconductor structure 21 is disposed in the middle of the interposer 11. The second semiconductor structure 22 and the third semiconductor structure 23 are disposed adjacent to the first side 21a of the first semiconductor structure 21, and the fourth semiconductor structure 24 and the fifth semiconductor structure 25 are disposed adjacent to the second side 21b of the first semiconductor structure 21. The second side 21b is opposite the first side 21a. Specifically, as shown in FIG. 4, the second semiconductor structure 22 is disposed adjacent to the corner C_{I2} of the interposer 11 and the corner C_{S2} of the substrate 65. The third semiconductor structure 23 is disposed adjacent to the corner C_{I1} of the interposer 11 and the corner C_{S1} of the substrate 65. The fourth semiconductor structure 24 is disposed adjacent to the corner C_{I4} of the interposer 11 and the corner C_{S4} of the substrate 65. The fifth semiconductor structure 25 is disposed adjacent to the corner C_{I3} of the interposer 11 and the corner C_{S3} of the substrate 65.

In some embodiments, the first semiconductor structure 21 has real electrical functions and transmits an electrical signal to one or more of the other semiconductor structures and the substrate 65 during operation. The semiconductor structures that have similar structural configurations (e.g., packages) and are arranged adjacent to the opposite corners of the interposer 11 and/or the corners of the substrate 65 would reduce and balance the overall stress of the semiconductor package P3. Thus, the coplanarity (COP) of the semiconductor package P3 can be improved. For example, when a semiconductor structure that is arranged adjacent to a corner of the interposer 11 (and a corner of the substrate 65) includes a device with real electrical functions and is in the form of a package, another semiconductor structure that is arranged adjacent to the opposite corner of the interposer 11 (and the opposite corner of the substrate 65) may be a dummy package instead of a dummy silicon die. Thus, the overall stress of the entire semiconductor package P3 can be reduced and balanced. The dummy package is a dummy structure that cannot provide any electrical signal to other semiconductor structures and the substrate 65, and this dummy structure is configured in the form of a package.

In some embodiments, when the second semiconductor structure 22 and the fourth semiconductor structure 24 have real electrical functions and transmit electrical signals to other semiconductor structures, one or both of the third semiconductor structure 23 and the fifth semiconductor structure 25 can be dummy packages to reduce and balance the overall stress, so the coplanarity (COP) of the interposer 11 and the substrate 65 can be improved. In one example, the first semiconductor structure 21 includes a SoC device, the second semiconductor structure 22 and the fourth semiconductor structure 24 each include a HBM device, and at least one of the third semiconductor structure 23 and the fifth semiconductor structure 25 is a dummy HBM package that is configured in the form of an HBM package but does not provide any real HBM function.

In some embodiments, when the third semiconductor structure 23 and the fifth semiconductor structure 25 have real electrical functions and transmit electrical signals to other semiconductor structures, one or both of the second semiconductor structure 22 and the fourth semiconductor structure 24 can be dummy packages to reduce and balance the overall stress, so the coplanarity (COP) of the interposer 11 and the substrate 65 can be improved. In one example, the first semiconductor structure 21 includes a SoC device, the third semiconductor structure 23 and the fifth semiconductor structure 25 each include a HBM device, and at least one of the second semiconductor structure 22 and the fourth semiconductor structure 24 is a dummy HBM package that is configured in the form of an HBM package but does not provide any real HBM function.

In addition, in some embodiments, when the third semiconductor structure 23 and the fourth semiconductor structure 24 have real electrical functions and transmit electrical signals to other semiconductor structures, one or both of the second semiconductor structure 22 and the fifth semiconductor structure 25 can be dummy packages to reduce and balance the overall stress, so the coplanarity (COP) of the interposer 11 and the substrate 65 can be improved. In one example, the first semiconductor structure 21 includes a SoC device, the third semiconductor structure 23 and the fourth semiconductor structure 24 each include a HBM device, and at least one of the second semiconductor structure 22 and the fifth semiconductor structure 25 is a dummy HBM package that is configured in the form of an HBM package but does not provide any real HBM function.

In some embodiments, when the second semiconductor structure 22 and the fifth semiconductor structure 25 have real electrical functions and transmit electrical signals to other semiconductor structures, one or both of the third semiconductor structure 23 and the fourth semiconductor structure 24 can be dummy packages to reduce and balance the overall stress, so the coplanarity (COP) of the interposer 11 and the substrate 65 can be improved. In one example, the first semiconductor structure 21 includes a SoC device, the second semiconductor structure 22 and the fifth semiconductor structure 25 each include a HBM device, and at least one of the third semiconductor structure 23 and the fourth semiconductor structure 24 is a dummy HBM package that is configured in the form of an HBM package but does not provide any real HBM function.

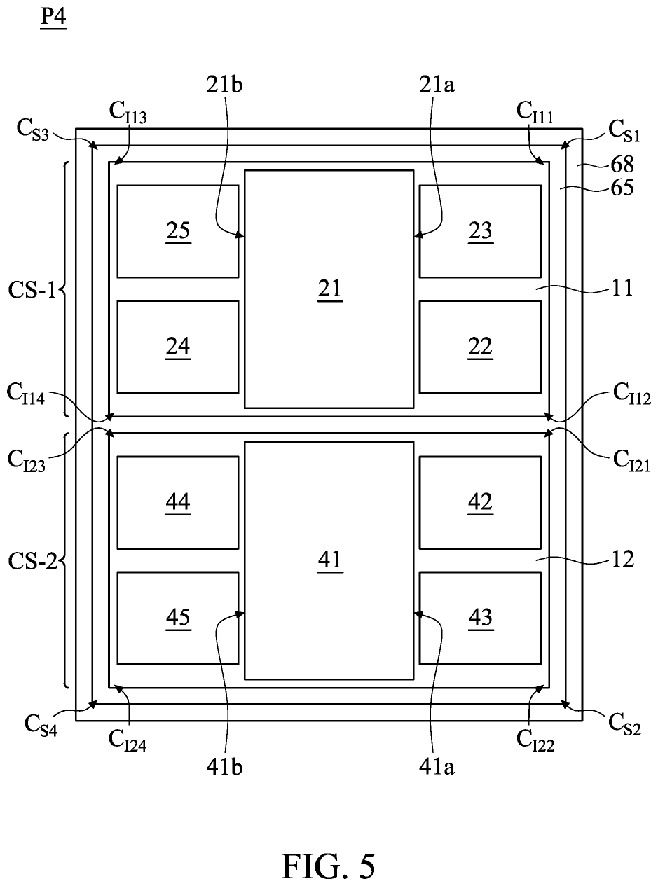

In addition, a semiconductor package may include more interposers over the substrate 65. FIG. 5 is a top view of an intermediate stage of a semiconductor package, in accordance with some embodiments of the present disclosure. The same or similar reference numerals or reference designators denote the same or similar elements (such as components or layers) in FIG. 3A-FIG. 3C, FIG. 4 and FIG. 5. For the purpose of brevity, the materials of the same or similar components/layers and processes of forming those components/layers are not repeated herein.

Referring to FIG. 5, a semiconductor package P4 with two structures over a substrate 65 is provided. Each structure may include an interposer and the features on the interposer, which are similar to or the same as the interposer 11 and the features on the interposer 11 in FIG. 4. The semiconductor package P4 in FIG. 5 may include a first structure CS-1 and a second structure CS-2 over the substrate 65.

Specifically, in some embodiments, the first structure CS-1 includes an interposer 11 over the substrate 65, a redistribution structure (not shown in FIG. 5, but has the same or similar structure of the redistribution structure 13 in FIG. 2) on the interposer 11, and several semiconductor structures (for example, including the first semiconductor structure 21, the second semiconductor structure 22, the third semiconductor structure 23, the fourth semiconductor structure 24 and the fifth semiconductor structure 25) on the redistribution structure. Structural details and materials of those semiconductor structures 21-25 have been described above, and are not repeated herein.

In some embodiments, the second structure CS-2 includes an interposer 12 over the substrate 65, a redistribution structure (not shown in FIG. 5, but has the same or similar structure of the redistribution structure 13 in FIG. 2) on the interposer 12, and several semiconductor structures (for example, including the sixth semiconductor structure 41, the seventh semiconductor structure 42, the eighth semiconductor structure 43, the ninth semiconductor structure 44 and the tenth semiconductor structure 45) on the redistribution structure. The seventh semiconductor structure 42 and the eighth semiconductor structure 43 are disposed adjacent to the first side 41a of the sixth semiconductor structure 41, and the ninth semiconductor structure 44 and the tenth semiconductor structure 45 are disposed adjacent to the second side 41b of the sixth semiconductor structure 41. The second side 41b is opposite the first side 41a.

The components of the second structure CS-2 may have the same or similar structural configuration and arrangement as that of the components of the first structure CS-1. In one example, the components of the first semiconductor structure 21, the second semiconductor structure 22, the third semiconductor structure 23, the fourth semiconductor structure 24 and the fifth semiconductor structure 25 have the same or similar structural configurations and arrangements as that of the sixth semiconductor structure 41, the seventh semiconductor structure 42, the eighth semiconductor structure 43, the ninth semiconductor structure 44 and the tenth semiconductor structure 45, respectively.

In some embodiments, the first semiconductor structure 21 and the sixth semiconductor structure 41 each may include a device (such as a SoC device) with real electrical function and may transmit electrical signal to the other semiconductor structures during operation. The second semiconductor structure 22, the fourth semiconductor structure 24, the seventh semiconductor structure 42 and the ninth semiconductor structure 44 each include another device (such as a HBM device) with real electrical functions and may transmit electrical signals to the other semiconductor structures during operation. At least one of the third semiconductor structure 23, the fifth semiconductor structure 25, the eighth semiconductor structure 43 and the tenth semiconductor structure 45 that is disposed adjacent to the corner C_{S1}, C_{S2}, C_{S3} or C_{S4} of the substrate 65 is a dummy package. For example, at least one of the third semiconductor structure 23, the fifth semiconductor structure 25, the eighth semiconductor structure 43 and the tenth semiconductor structure 45 is a dummy HBM package that is configured in the form of an HBM package but does not provide any real HBM function. That is, at least one of the third semiconductor structure 23, the fifth semiconductor structure 25, the eighth semiconductor structure 43 and the tenth semiconductor structure 45 is electrically insulated from the other semiconductor structures and the substrate 65 during operation.

In one example, the second semiconductor structure 22, the fourth semiconductor structure 24, the seventh semiconductor structure 42 and the ninth semiconductor structure 44 each include a HBM device. The third semiconductor structure 23 that is disposed adjacent to the corner C_{S1}, the fifth semiconductor structure 25 that is disposed adjacent to the corner C_{S3}, the eighth semiconductor structure 43 that is disposed adjacent to the corner C_{S2} and the tenth semiconductor structure 45 that is disposed adjacent to the corner C_{S4} are dummy HBM packages. Accordingly, the stress of the interposers 11 and 12 and the substrate 65 of the semiconductor package P4 can be reduced and balanced. The coplanarity (COP) of the semiconductor package P4 can be improved.

In addition, stress simulation of a conventional semiconductor package (including one or more dummy silicon dies adjacent to the corners of the substrate) and an embodied semiconductor package (including one or more dummy package adjacent to the corners of the substrate as shown in FIG. 1 to FIG. 5) on the entire semiconductor package and the underfill materials were conducted.

Stress simulation shows that if the stress ratio of the entire conventional semiconductor package is used as a reference value (stress ratio is 1), the stress ratio of the entire semiconductor package of the embodiment is in a range of about 0.9 to 0.95.

In addition, stress simulation shows that if the stress ratio of the conventional semiconductor package at an underfill layer that is between the semiconductor structures and an underlying interposer (e.g. corresponding to the position of the first underfill layer 27 or 47 in the semiconductor package) is used as a reference value (stress ratio is 1), the stress ratio of the semiconductor package of the embodiment at the first underfill layer 27 (or the first underfill layer 47) is about 0.85.

In addition, stress simulation shows that if the stress ratio of the conventional semiconductor package at the underfill layer that is between the interposer and the substrate (e.g. corresponding to the position of the second underfill layer 33 or 37 in the semiconductor package) is used as a reference value (stress ratio is 1), the stress ratio of the semiconductor package of the embodiment at the second underfill layer 33 (or the second underfill layers 37) is about 0.9.

According to the aforementioned stress simulation results, it proves that the stresses on the entire semiconductor package and the underfill layers are significantly reduced.

In addition, coplanarity (COP) simulation of a conventional semiconductor package (about 9.8 mil) and an embodied semiconductor package (about 9.2 mil) are also conducted. The result shows that the coplanarity of the substrate 65 of the embodied semiconductor package has been improved.

In addition, the conventional semiconductor package (including one or more dummy silicon dies adjacent to the corners of the substrate) and the embodied semiconductor package (including one or more dummy package adjacent to the corners of the substrate as shown in FIG. 1 to FIG. 5) were subjected to reliability testing through thermal cycling. The reliability results show that the conventional semiconductor package didn't pass 850 thermal cycling between −40° C. and 125° C. The reliability results also show that the thermal cycling induces delamination and cracking failure of the underfill material layers of the conventional semiconductor package. However, the embodied semiconductor package passed 850 thermal cycling between −40° C. and 125° C. The reliability results also show that no cracking and delamination was found in the underfilled material layers (such as the first underfill layer 27/47 and the second underfill layer 33/37) of the embodied semiconductor package after 850 thermal cycling.

According to some embodiments described above, the semiconductor packages achieve several advantages. In some embodiments, the semiconductor structures that are arranged adjacent to the opposite corners (or the opposite edges) of the interposer and the opposite corners (or the opposite edges) of the substrate have similar structural configurations (e.g., packages) to reduce and balance the overall stress of the semiconductor package. For example, one semiconductor structure that is disposed adjacent to a corner or an edge of the substrate is configured as a dummy package. In some embodiments, the stress of the interposer (on which the semiconductor structures are mounted) and the stress of the substrate (on which one or more interposers are mounted) can be reduced and balanced. Thus, the coplanarity (COP) of the entire semiconductor package can be improved, in accordance with some embodiments of the present disclosure. In addition, in some embodiments, the semiconductor packages pass thermal cycling test, and no cracking and delamination occur in the underfilled material layers of the semiconductor packages after thermal cycling test. Thus, the thermal reliability of the semiconductor packages in accordance with some embodiments of the present disclosure is significantly improved.

It should be noted that the details of the structures and fabrications of the embodiments are provided for exemplification, and the described details of the embodiments are not intended to limit the present disclosure. It should be noted that not all embodiments of the invention are shown. Modifications and variations can be made without departing from the spirit of the disclosure to meet the requirements of the practical applications. Thus, there may be other embodiments of the present disclosure which are not specifically illustrated. Furthermore, the accompanying drawings are simplified for clear illustrations of the embodiment. Sizes and proportions in the drawings may not be directly proportional to actual products. Thus, the specification and the drawings are to be regard as an illustrative sense rather than a restrictive sense.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A semiconductor package, comprising:
an interposer over a substrate that includes interconnect traces;
a redistribution structure on the interposer;
a first semiconductor structure on the redistribution structure that is disposed on the interposer, wherein the first semiconductor structure includes a first semiconductor die and a first encapsulant that encapsulates the first semiconductor die;
a second semiconductor structure on the redistribution structure, wherein the second semiconductor structure includes a second semiconductor die and a second encapsulant that encapsulates the second semiconductor die; and
a third semiconductor structure on the redistribution structure and adjacent to a corner or an edge of the substrate in a top plan view of the substrate, wherein the third semiconductor structure includes a third semiconductor die and a third encapsulant that encapsulates the third semiconductor die,
wherein the third semiconductor structure is electrically insulated from the substrate, the first semiconductor structure and the second semiconductor structure.

2. The semiconductor package as claimed in claim 1, wherein no electrical signal is transmitted between the third semiconductor structure and any of the substrate, the first semiconductor structure and the second semiconductor structure.

3. The semiconductor package as claimed in claim 1, wherein the second semiconductor structure and the third semiconductor structure are disposed at opposite sides of the first semiconductor structure.

4. The semiconductor package as claimed in claim 1, wherein the third semiconductor structure is disposed adjacent to a corner or an edge of the interposer in the top plan view of the interposer.

5. The semiconductor package as claimed in claim 1, wherein the first semiconductor structure and the second semiconductor structure are electrically connected to the substrate by the redistribution structure and conductive pillars of the interposer.

6. The semiconductor package as claimed in claim 5, wherein the third semiconductor die of the third semiconductor structure is grounded.

7. The semiconductor package as claimed in claim 1, wherein an arrangement of the second semiconductor die and the second encapsulant is identical to an arrangement of the third semiconductor die and the third encapsulant.

8. The semiconductor package as claimed in claim 1, further comprising:
conductive components disposed between the redistribution structure and the first semiconductor structure, the second semiconductor structure and the third semiconductor structure;
an underfill layer surrounding the conductive components and filling gaps between the conductive components, wherein the underfill layer is adjacent to the third encapsulant; and
a molding compound surrounding the first semiconductor structure, the second semiconductor structure, the third semiconductor structure and the underfill layer.

9. The semiconductor package as claimed in claim 1, wherein the third encapsulant of the third semiconductor structure comprises the same material as the second encapsulant of the second semiconductor structure.

10. The semiconductor package as claimed in claim 1, wherein the second semiconductor structure and the third semiconductor structure are disposed adjacent to a first side of the first semiconductor structure, and the third semiconductor structure is disposed adjacent to a first corner of the interposer in a top plan view of the interposer.

11. The semiconductor package as claimed in claim 10, further comprising:
a fourth semiconductor structure disposed over the redistribution structure, wherein the fourth semiconductor structure includes a fourth semiconductor die and a fourth encapsulant that encapsulates the fourth semiconductor die; and
a fifth semiconductor structure disposed over the redistribution structure, wherein the fifth semiconductor structure includes a fifth semiconductor die and a fifth encapsulant that encapsulates the fifth semiconductor die,
wherein the fifth semiconductor structure is electrically insulated from the substrate, the first semiconductor structure and the fourth semiconductor structure, and
wherein the third semiconductor structure and the fifth semiconductor structure are disposed adjacent to two corners of the substrate in the top plan view of the substrate.

12. The semiconductor package as claimed in claim 11, wherein the fifth semiconductor structure is disposed adjacent to a second corner of the interposer in the top plan view of the interposer.

13. The semiconductor package as claimed in claim 11, wherein the fourth semiconductor structure and the fifth semiconductor structure are disposed adjacent to a second side of the first semiconductor structure, wherein the second side is opposite to the first side of the first semiconductor structure.

14. The semiconductor package as claimed in claim 11, wherein the fifth semiconductor structure is further electrically insulated from the second semiconductor structure and the third semiconductor structure.

15. A semiconductor package, comprising:
a first structure and a second structure over a substrate that includes interconnect traces, and the second structure is adjacent to the first structure, wherein each of the first structure and the second structure comprises:
an interposer over the substrate;
a redistribution structure on the interposer;
a first semiconductor structure on the redistribution structure that is disposed on the interposer, wherein the first semiconductor structure includes a first semiconductor die and a first encapsulant that encapsulates the first semiconductor die;
a second semiconductor structure on the redistribution structure, wherein the second semiconductor structure includes a second semiconductor die and a second encapsulant that encapsulates the second semiconductor die; and
a third semiconductor structure on the redistribution structure, wherein the third semiconductor structure includes a third semiconductor die and a third encapsulant that encapsulates the third semiconductor die, wherein the third semiconductor structure is electrically insulated from the substrate, the first semiconductor structure and the second semiconductor structure,
wherein the third semiconductor structures of the first structure and the second structure are disposed adjacent to two corners or two edges of the substrate in a top plan view of the substrate.

16. The semiconductor package as claimed in claim 15, wherein no electrical signal is transmitted from the third semiconductor structures of the first structure and the second structure to any of the first semiconductor structures and the second semiconductor structures of the first structure and the second structure.

17. The semiconductor package as claimed in claim 15, wherein the third semiconductor structure of each of the first structure and the second structure is disposed adjacent to a corner or an edge of the interposer in the top plan view of the interposer.

18. The semiconductor package as claimed in claim 15, wherein in each of the first structure and the second structure, the first semiconductor structure and the second semiconductor structure are electrically connected to the substrate by the redistribution structure and conductive pillars of the interposer, while the third semiconductor die of the third semiconductor structure is grounded.

19. The semiconductor package as claimed in claim 15, wherein in each of the first structure and the second structure, the second semiconductor structure and the third semiconductor structure are disposed at opposite sides of the first semiconductor structure.

20. The semiconductor package as claimed in claim 15, wherein in each of the first structure and the second structure, an arrangement of the second semiconductor die and the second encapsulant is identical to an arrangement of the third semiconductor die and the third encapsulant.

21. The semiconductor package as claimed in claim 15, wherein in each of the first structure and the second structure, the third encapsulant comprises the same material as the second encapsulant.

22. The semiconductor package as claimed in claim 15, wherein in each of the first structure and the second structure, the second semiconductor structure and the third semiconductor structure are disposed adjacent to a first side of the first semiconductor structure, and each of the first structure and the second structure further comprises:
a fourth semiconductor structure disposed over the redistribution structure, wherein the fourth semiconductor structure includes a fourth semiconductor die and a fourth encapsulant that encapsulates the fourth semiconductor die; and
a fifth semiconductor structure disposed over the redistribution structure, wherein the fifth semiconductor structure includes a fifth semiconductor die and a fifth encapsulant that encapsulates the fifth semiconductor die,
wherein the fifth semiconductor structure is electrically insulated from any of the substrate, the first semiconductor structure, the second semiconductor structure, the third semiconductor structure and the fourth semiconductor structure.

23. The semiconductor package as claimed in claim 22, wherein in each of the first structure and the second structure, the fourth semiconductor structure and the fifth semiconductor structure are disposed adjacent to a second side of the first semiconductor structure, wherein the second side is opposite to the first side of the first semiconductor structure.

24. The semiconductor package as claimed in claim 22, wherein in a top plan view of the interposer of the first structure, the third semiconductor structure and the fifth semiconductor structure are disposed adjacent to a first corner and a third corner of the interposer of the first structure, respectively.

25. The semiconductor package as claimed in claim 24, wherein in a top plan view of the interposer of the second structure, the third semiconductor structure and the fifth semiconductor structure are disposed adjacent to a second corner and a fourth corner of the interposer of the second structure, respectively.

26. The semiconductor package as claimed in claim 22, wherein in the top plan view of the substrate, the third semiconductor structure and the fifth semiconductor structure of the first structure are disposed respectively adjacent to a first corner and a third corner of the substrate, wherein the first corner is opposite the third corner.

27. The semiconductor package as claimed in claim 26, wherein in the top plan view of the substrate, the third semiconductor structure and the fifth semiconductor structure of the second structure are respectively disposed adjacent to a second corner and a fourth corner of the substrate, wherein the second corner is opposite the fourth corner.
